(19) United States
(12) Patent Application Publication
(10) Pub. No.: US 2019/0226088 A1
(43) Pub. Date: Jul. 25, 2019

(54) HIGH TEMPERATURE FACEPLATE WITH THERMAL CHOKE AND COOLING

(71) Applicant: Applied Materials, Inc., Santa Clara, CA (US)

(72) Inventors: Yuxing ZHANG, Santa Clara, CA (US); Sanjeev BALUJA, Campbell, CA (US); Kaushik ALAYAVALLI, Sunnyvale, CA (US); Kalyanjit GHOSH, San Jose, CA (US); Daniel HWUNG, Los Gatos, CA (US)

(21) Appl. No.: 16/255,120

(22) Filed: Jan. 23, 2019

Related U.S. Application Data
(60) Provisional application No. 62/621,398, filed on Jan. 24, 2018.

(51) Int. Cl. C23C 16/455

(52) U.S. Cl. CPC C23C 16/45559

(57) ABSTRACT

Embodiments herein generally relate to gas distribution apparatuses. In one aspect, the disclosure relates to a faceplate having a plurality of apertures therethrough. Thermal chokes are disposed on the faceplate radially outward of the apertures. Seals are disposed at distal ends of the thermal chokes and are thermally separated from a body of the faceplate by the thermal chokes.

### CROSS-REFERENCE TO RELATED APPLICATIONS

This application claims benefit of U.S. provisional patent application Ser. No. 62/621,398, filed Jan. 24, 2018, which is herein incorporated by reference in its entirety.

### BACKGROUND

### Field

Embodiments of the present disclosure generally relate to a faceplate for use in substrate processing chambers.

### Description of the Related Art

In the fabrication of integrated circuits, deposition processes such as chemical vapor deposition (CVD) or atomic layer deposition (ALD) are used to deposit films of various materials upon semiconductor substrates. In other operations, a layer altering process, such as etching, is used to expose a portion of a layer for further depositions. Often, these deposition or etching processes are used in a repetitive fashion to fabricate various layers of an electronic device, such as a semiconductor device.

Fabricating a defect free semiconductor device is desirable when assembling an integrated circuit. Contaminants or defects present in a substrate can cause manufacturing defects within the fabricated device. For example, contaminants present in the processing chamber or the process gas delivery system may be deposited on the substrate, causing defects and reliability issues in the semiconductor device fabricated thereon. Accordingly, it is desirable to form a defect-free film when performing a deposition process. However, with conventional deposition devices, the layered films may be formed with defects and contaminants.

Therefore, what is needed in the art are improved apparatus for film deposition.

### SUMMARY

In one embodiment, a faceplate for a processing chamber has a body having an upper surface and a lower surface. A plurality of apertures is disposed between the upper surface and the lower surface. A plurality of thermal chokes is disposed on the body surrounding the apertures. A first thermal choke is disposed on the upper surface of the body and a second thermal choke is disposed on the lower surface of the body.

In one embodiment, a faceplate for a processing chamber has a body having a plurality of apertures therethrough. A first thermal choke extends from a first surface and a second thermal choke extends from a second surface. Each thermal choke has a plurality of first cutouts extending partially through a width of the thermal choke and a plurality of second cutouts extending partially through the width of the thermal choke. Each second cutout is disposed between adjacent first cutouts. The thermal chokes further include cooling channels.

In one embodiment, a chamber for processing a substrate has a body. A lid is coupled to the body defining a processing volume. A faceplate is coupled to the lid. The faceplate has a body having a first surface and a second surface with a plurality of apertures disposed therethrough. A first thermal choke extends from the upper surface of the faceplate body, and a second thermal choke extending from lower surface of the faceplate body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 illustrates a schematic view of a processing chamber, according to one embodiment of the disclosure.

FIG. 2 illustrates a cross-sectional schematic view of a faceplate according to one embodiment of the disclosure.

FIG. 3 illustrates a cross-sectional schematic view of a faceplate according to one embodiment of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein generally relate to faceplates for use in substrate processing. In one embodiment, the disclosure herein relates to a faceplate having a plurality of apertures therethrough. Thermal chokes are disposed around the perimeter of the faceplate and surrounding the apertures. The faceplate optionally includes a heater configured to heat the faceplate. When the faceplate is positioned in a processing chamber, a seal is disposed outwardly of or in contact with, the thermal chokes. The thermal chokes facilitate thermal isolation or a reduction in thermal transfer between the heater of the faceplate and the seal.

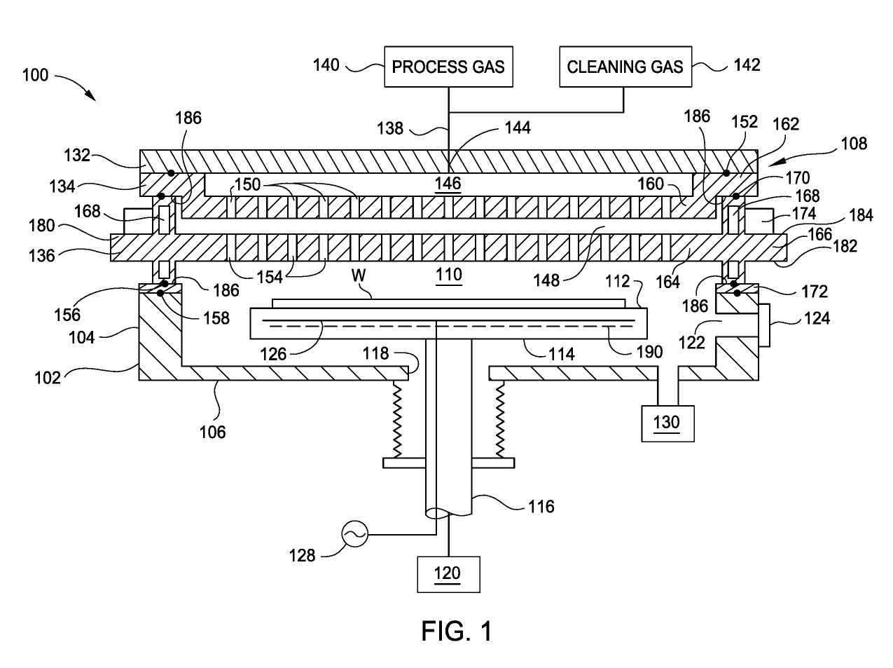

FIG. 1 illustrates a schematic sectional view of a process chamber 100 according to one embodiment. The process chamber 100 includes a body 102 having a sidewall 104 and base 106. A lid assembly 108 couples to the body 102 to define a process volume 110 therein. In one embodiment, the body 102 is formed from a metallic material, such as aluminum or stainless steel, but any material suitable for use with the process therein may be utilized. A substrate support is disposed within the process volume 110 for supporting a substrate W thereon. The substrate support includes a support body 114 coupled to a shaft 116. The shaft 116 is coupled to a lower surface of the support body 114 and extends out of the body 102 through an opening 118 in the base 106. The shaft 116 is coupled to an actuator 120 to vertically actuate the shaft 116, and support body 114 coupled thereto, between a substrate loading position and a substrate processing position. A vacuum system 130 is fluidly coupled to the process volume 110 in order to evacuate gases from the process volume 110.

To facilitate processing of a substrate W in the process chamber 100, the substrate W is disposed the support body 114 opposite of the shaft 116. A port 122 is formed in the sidewall 104 to facilitate ingress and egress of the substrate W into the process volume 110. A door 124, such as a slit valve, is actuated to selectively enable the substrate W to pass through the port 122 to be loaded onto, or removed from, the support body 114. An electrode 126 is optionally disposed within the support body 114 and electrically coupled to a power source 128 through the shaft 116. The electrode 126 is selectively biased by the power source 128 to create an electromagnetic field to chuck the substrate W to the support body 114. In certain embodiments, a heater 190, such as a resistive heater, is disposed within the support body 114 to heat the substrate W disposed thereon.

The lid assembly 108 includes a lid 132, a blocker plate 134, and a faceplate 136. The blocker plate 134 includes a recessed circular distribution portion 160 surrounded by an annular extension 162. The blocker plate 134 is disposed between the lid 132 and the faceplate 136 and coupled to each of the lid 132 and the faceplate 136 at the annular extension 162. The lid 132 couples to an upper surface of the annular extension 162 opposite the body 102. The faceplate 136 couples to a lower surface of the annular extension 162. A first volume 146 is defined between the blocker plate 134 and the lid 132. A second volume 148 is further defined between the blocker plate 134 and the faceplate 136. A plurality of apertures 150 are formed through the distribution portion 160 of the blocker plate 134 and facilitate fluid communication between the first volume 146 and the second volume 148.

An inlet port 144 is disposed within the lid 132. The inlet port 144 is coupled to a gas conduit 138. The gas conduit 138 enables a gas to flow from a first gas source 140, such as a process gas source, through the inlet port 144 into the first volume 146. In one embodiment, a second gas source 142, such as a cleaning gas source, is optionally coupled to the gas conduit 138.

In one embodiment, the first gas source 140 supplies a process gas, such as an etching gas or a deposition gas, to the process volume 110 to etch or deposit a layer on the substrate W. The second gas source 142 supplies a cleaning gas to the process volume 110 in order to remove particle depositions from internal surfaces of the processing chamber 100. To facilitate processing, a remote plasma source (not shown) may be positioned in line with the first gas source 140, the second gas source 142, or both the first gas source 140 and the second gas source 142 in order to generate ionized species. A seal 152, such as an O-ring, is disposed between the blocker plate 134 and the lid 132 at the annular extension 162 surrounding the first volume 146 in order to isolate the process volume 110 from the external environment, enabling maintenance of a vacuum therein.

An annular isolator 172 is disposed between the body 102, specifically the sidewall 104, and the faceplate 136. A seal 156, such as an O-ring, is disposed between the isolator 172 and the faceplate 136. The seal 156 isolates the process volume 110 from the external environment and facilitates maintenance of a vacuum therein. The isolator 172 is formed from a thermally insulating and/or electrically insulating material such as a ceramic. The isolator 172 reduces heat transfer from the faceplate 136 to the body 102. A second seal 158 is disposed between the isolator 172 and the body 102. In certain embodiments, the seal 158 is an O-ring. In other embodiments, the seal 158 is a bonding material layer between, and coupling, the body 102 and the isolator 172.

Faceplate 136 is disposed between the blocker plate 134 and the support body 114. In one embodiment, the faceplate 136 has a circular body, but shapes such as square or ovoid, are also contemplated. In one embodiment, the faceplate 136 is formed from a thermally conductive material. In certain embodiments, the faceplate 136 is formed from a metal such as aluminum or stainless steel, however, dielectrics and/or ceramics such as aluminum nitride and aluminum oxide are also contemplated. It is contemplated that any material suitable to resist degradation due to processing temperatures may be utilized.

The faceplate 136 has a distribution portion 164 and a coupling portion 166 disposed radially outward of the distribution portion 164. The distribution portion 164 is disposed between the process volume 110 and the second volume 148. The coupling portion 166 surrounds the distribution portion 164 at a periphery of the faceplate 136. The coupling portion 166 includes a radially extending flange 180, having an upper surface 184 and a lower surface 182.

Apertures 154 are disposed through the faceplate 136 within the distribution portion 164. The apertures 154 enable fluid communication between the process volume 110 and the second volume 148. During operation, a gas is permitted to flow from the inlet port 144 into the first volume 146, through apertures 150 in the blocker plate 134, and into the second volume 148. From the second volume 148, the gas flows through the apertures 154 in the faceplate 136 into the process volume 110. The arrangement and sizing of the apertures 154 enable the selective flow of the gas into the process volume 110 in order to achieve desired gas distribution. For example, a uniform distribution across the substrate W may be desired for certain processes.

One or more heaters 174 are disposed in contact with the faceplate 136, for example, on an upper surface 184 of the coupling portion 166. The heaters 174 may be any mechanism capable of providing heat to the faceplate 136. In certain embodiments, the heater 174 is a cartridge heater that is easily coupled to a surface of the flange 180, such as upper surface 184. In other embodiments, the heaters 174 include a resistive heater, which may be embedded within and encircling the faceplate 136, such as embedded within the flange 180. In further embodiments, the heaters 174 include a channel (not shown) that flows a heated fluid therethrough. The heaters 174 heat the faceplate to a desired temperature, for example, 300 F, 400 F, 500 F, or higher. The inventors have surprisingly discovered that increasing the temperature of the faceplate during processing, such as chemical vapor deposition process, results in significantly less contaminant particle deposition on the substrate W.

Thermal chokes 168 extend from the flange 180 of the faceplate 136. As illustrated in FIG. 1, the thermal chokes 168 extend perpendicularly in a vertical orientation from the upper surface 184 and the lower surface 182 of the flange 180. The thermal chokes 168 circumscribe the distribution portion 164 of the faceplate 136. Further, the thermal chokes 168 are disposed inwardly the heater 174. The thermal chokes 168 minimize the heat transfer between one or more of the distribution portion 164, the flange 180, and the heater 174, and a gasket seating surface 186 of the thermal choke 168. Therefore, the distribution the gasket seating surfaces 186 is maintained at different temperatures than the distribution portion 164, the flange 180, and the heater 174 during processing. The temperature differential across the thermal choke 168 may be, for example, 50 F, 100 F, 150 F, or higher. For example, the distribution portion 164 can be heated to 350 F by the heaters 174 while the gasket seating surfaces 186 are maintained at 100 F due to the presence of the thermal choke 168. Thus, the faceplate 136 is capable of being heated to a desired temperature to reduce particle generation within the processing chamber 100, while maintaining seals 156, 170 below the degradation temperature of the seals 156, 170.

The thermal choke 168 may be any design or mechanism that limits heat transfer from the distribution portion 164. In certain embodiments, the thermal choke 168 is an annular cutout defining a thin bridge between the gasket seating surface 186 and the distribution portion 164. In further embodiments, the thermal choke 168 is a series of nested channels, spaced cooling fins, or the like.

Both seals 156, 170 are disposed adjacent the gasket seating surfaces 186 of the faceplate 136 outwardly from the thermal choke 168. In this configuration, the seals 156, 170 are O-rings formed from materials such as polytetrafluoroethylene (PTFE), rubber, or silicone. Other seal designs, such as sheet gaskets or bonds, are also contemplated. In conventional designs, a faceplate is generally not heated to the high temperatures described herein because the sealing materials degrade at elevated temperatures, such as 250 F or above. However, by utilizing the thermal choke 168 as described herein, an inner portion of faceplate 136 proximate to the process volume 110 can be heated to elevated temperatures while an outer portion, adjacent seals 156, 170, is maintained at a lower temperature. Thus, contaminant particle disposition on a substrate W being processed is limited while the seals 156, 170 are simultaneously protected from thermally-induced degradation. Therefore, a seal is maintained around the process volume 110 while the faceplate 136 is heated to high temperatures.

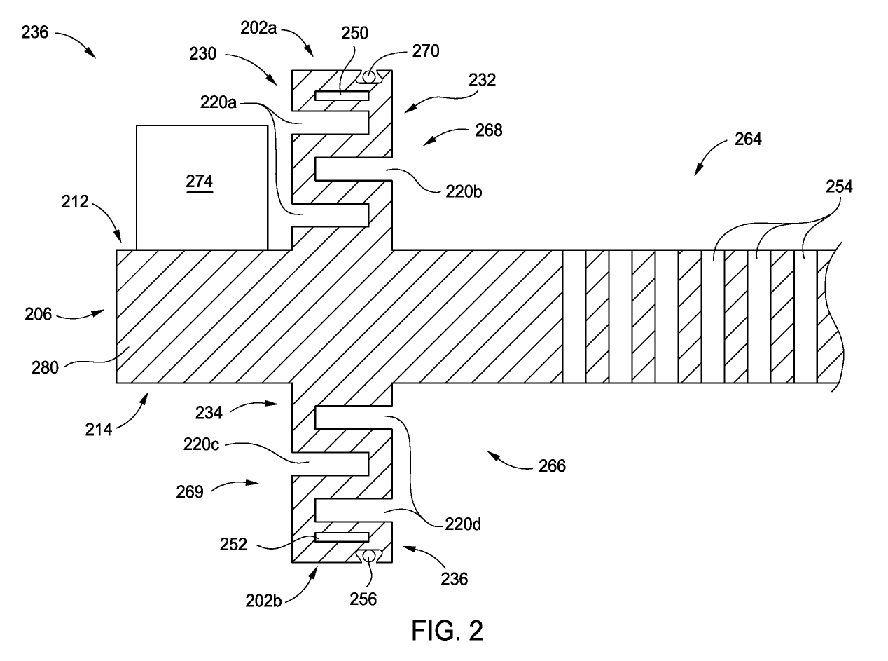

FIG. 2 illustrates a schematic partial cross-section of a faceplate 236 having a dual thermal choke, according to one embodiment. The faceplate 236 is similar to the faceplate 136, but optionally utilizes a cooling channel. The faceplate 236 may be used in place of the faceplate 136 shown in FIG. 1. In one embodiment, the faceplate 236 has a circular body including a central distribution portion 264 encircled by a coupling portion 266. The coupling portion 266 of the faceplate 236 includes thermal chokes 268, 269 which are disposed between a heater 274 and apertures 254. A flange 280 extends from, and surrounds, the distribution portion 264 at a peripheral region thereof. The flange 280 has an upper surface 212 and a lower surface 214. The upper surface 212 and the lower surface 214 are joined by a radially outward outer surface 206 defining a width of the flange 280. The flange 280 and thermal chokes 268, 269 together form the coupling portion 266. In FIG. 2, only an enlarged peripheral portion of the faceplate 236, including thermal chokes 268, 269, is shown for clarity.

In one embodiment, the faceplate 236 is formed from a thermally conductive material. In some embodiments, the faceplate 236 is formed from a metallic material, for example, aluminum or stainless steel. In further embodiments, the faceplate 236 is formed from aluminum nitride or aluminum oxide. Any thermally conductive material may be used to form the faceplate 236.

Thermal chokes 268, 269 are formed on the flange 280 and extend vertically from the upper surface 212 and the lower surface 214. The thermal choke 268 extends away from the flange 280 at the upper surface 212 to form an extension, herein representatively extending upward. The thermal choke 269 extends away from the flange 280 at the lower surface 214 to form an extension, herein representatively extending downward.

The thermal choke 268 includes one or more interleaved first and second annular channels 220a, 220b (here, three are shown), which form a baffle or serpentine configuration. The thermal choke 268 has a radially outward surface 230 and a radially inner surface 232. The first annular channels 220a extend from the outer surface 230 towards the inner surface 232, while the second annular channel 220b extends from the inner surface 232 towards the outer surface 230. Thus, the first and second annular channels 220a, 220b are disposed on opposite sides of the thermal choke 268. The second annular channel 220b is disposed in an alternating fashion between adjacent first annular channels 220a.

Like the thermal choke 268, the thermal choke 269 includes one or more interleaved annular channels 220c, 220d (three are shown), which form a baffle or serpentine configuration. The thermal choke 268 has a radially outward outer surface 234 and a radially inner surface 238. The first annular channel 220c extends from the outer surface 234 towards the inner surface 238 while the second annular channels 220d extend from the inner surface 238 towards the outer surface 234. Thus, the first and second annular channels 220c, 220d are disposed on opposite sides of the thermal choke 269. The first annular channel 220c is disposed in an alternating fashion between adjacent second annular channels 220d.

In one embodiment, the channels 220a-220d do not span an entire width of a respective thermal chokes 268, 269. That is, the channels 220a-220d define thin bridges between each channel end and the opposing surface. For example, first annular channels 220a have a bridge between the ends thereof and the inner surface 232. In this configuration, the channels 220a-220d greatly increase the surface area for the convection of heat to the external environment around the faceplate 236. Additionally, the cross-section area and/or mass available to conduct heat from the distribution portion 264 towards an outer surface is greatly reduced. Further, here, six channels 220a-220d are shown but any suitable number and configuration thereof to limit heat transfer may be utilized.

It is understood that the size, shape, and number of channels 220a-220d may be selected in relation to a desired rate of heat transfer across the thermal choke 268. Further, the depth, width, and cross section of the channels 220a-220d may be adjusted as desired. Still further, the orientation of the channels may be altered. For example, rather than horizontal channels, the channels may be oriented vertically between and parallel to the outer surfaces 230, 234 and the inner surfaces 232, 238. Any arrangement of channels, gaps, grooves, recesses, or cutouts capable of minimizing heat transfer may be utilized.

Seal 270 is disposed within a dovetailed groove in a gasket surface 202a of the thermal choke 268. Seal 256 is similarly disposed within a dovetailed groove in a gasket surface 202b of the thermal choke 269. The seals 270, 256 are disposed outwardly of the channels 220a-220d forming the thermal chokes 268, 269. In this arrangement, thermal heat transfer to the seals 270, 256 from the distribution portion 264 and the heater 274 is reduced or mitigated. Therefore, the heater 274 can heat the faceplate 236, and distribution portion 264 therein, while the seals 270, 256 in the gasket surfaces 202a, 202b are maintained in a temperature range which does not accelerate degradation of the seals 270, 256. In certain embodiments, seals 270, 256 are disposed directly on the surfaces 202a, 202b respectively.

In one embodiment, cooling channels 250, 252 are optionally disposed within the thermal chokes 268, 269. The cooling channel 250 is disposed between the channels 220a, 220b and the gasket surface 202a. The cooling channel 252 is disposed between the channels 220c, 220d and the gasket surface 202b. A fluid, such as air, water, or ethylene glycol, is circulated through the cooling channels 250, 252. The fluid provides an additional cooling medium to remove heat from the thermal chokes 268, 269. Therefore, the heat transfer from the heater 274 and the faceplate deposition region 208 to the gasket seating surfaces 202a, 202b having seals 270, 256 therein is further reduced. The cooling channels 250, 252 may further be coupled to a cooling system, such as a heat exchanger, to control a temperature of the fluid therein.

In FIG. 2, a single channel is shown to represent each of the cooling channels 250, 252. However, it is contemplated that the cooling channels 250, 252 may be any suitable number of cooling channels or any shape and/or configuration. For example, a plurality of circular channels may be used. Additionally, the thermal chokes 268, 269 may be formed from two members wherein the cooling channels 250, 252 are defined by recesses within one or both of the members. Still further, the cooling channels 250, 252 may be used without a liquid, and instead, airgaps may be defined between the channels 220a-220d and the gasket seating surfaces 202a, 202b.

The heater 274 is shown disposed on the upper surface 212 of the flange 280 in FIG. 2. In this embodiment, the heater 274 is a cartridge heater. However, other manners of heating the faceplate 236 may be used. Additionally, the heater 274 may be disposed in other locations, such as on the lower surface 214 of the flange 280 or the outer surface 206. More than one heater 274 may also be used, such as one heater 274 on the upper surface 212 and one heater 274 on the lower surface 214. Still further, the heater 274 may be disposed radially inward from the thermal chokes 268, 269.

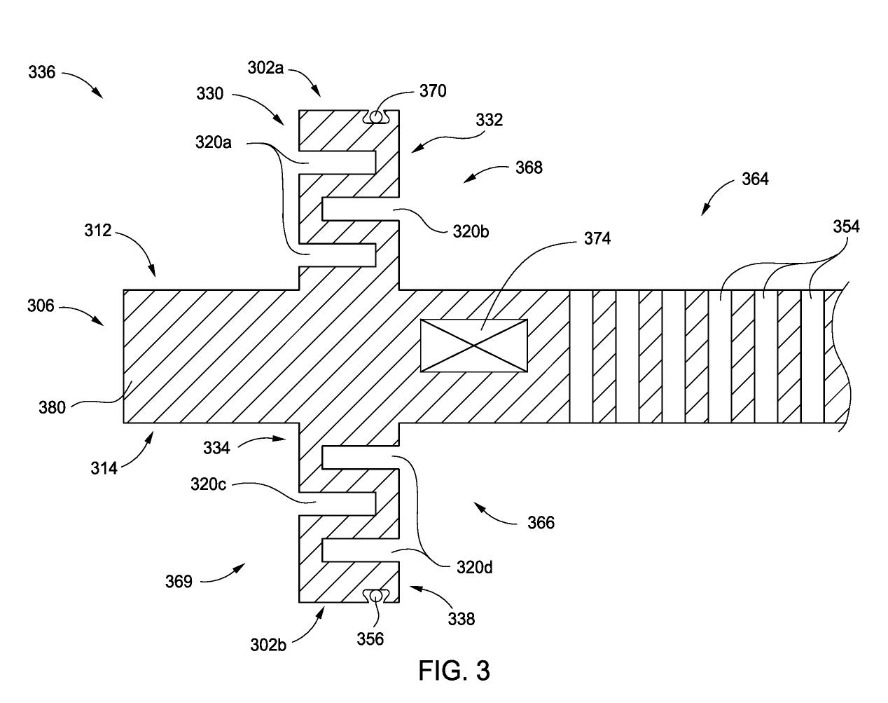

FIG. 3 illustrates a cross-sectional schematic of a faceplate 336 having a dual thermal choke. The faceplate 336 is similar to the faceplate 236 and the faceplate 136, but utilizes a different heater configuration. The faceplate 336 may be used in place of the faceplate 136 shown in FIG. 1. In one embodiment, the faceplate 336 has a circular body including a central distribution portion 364 encircled by a coupling portion 366. The coupling portion 366 of the faceplate 336 includes thermal chokes 368, 369 disposed radially outwardly of apertures 354. A flange 380 extends from, and surrounds, the distribution portion 364 at a peripheral region thereof. The flange 380 has an upper surface 312 and a lower surface 314. The upper surface 312 and the lower surface 314 are joined by a radially outward surface 306 therebetween defining a width of the flange 380. The flange 380 and thermal chokes 368, 369 together form the coupling portion 366. In FIG. 3, only an enlarged peripheral portion of the faceplate 336, including thermal chokes 368, 369, is shown for clarity.

The faceplate 336 is generally formed from a thermally conductive material. In one embodiment, the faceplate 336 is formed from a metallic material, for example, aluminum or stainless steel. In other embodiments, the faceplate 336 is formed from aluminum nitride or aluminum oxide. Any thermally conductive material may be used to form the faceplate 336.

Thermal chokes 368, 369 are formed on the flange 380 and extend vertically from the upper surface 312 and the lower surface 314. The thermal choke 368 extends away from the flange 380 at the upper surface 312 to form an extension, herein representatively extending upward. The thermal choke 369 extends away from the flange 380 at the lower surface 314 to form an extension, herein representatively extending downward.

The thermal choke 368 includes one or more interleaved annular channels 320a, 320b (here, three are shown), which form a baffle or serpentine configuration. The thermal choke 368 has a radially outward outer surface 330 and a radially inner surface 332. The first annular channels 320a extend from the outer surface 330 towards the inner surface 332 while the second annular channel 320b extends from the inner surface 332 towards the outer surface 330. Thus, the annular channels 320a, 320b are disposed on opposite sides of the thermal choke 368. The second annular channel 320b is disposed in an alternating fashion between adjacent first annular channels 320a.

Like the thermal choke 368, the thermal choke 369 includes one or more interleaved annular channels 320c, 320d (here, three are shown), which form a baffle or serpentine configuration. The thermal choke 368 has a radially outward outer surface 334 and a radially inner surface 338. The first annular channel 320c extends from the outer surface 334 towards the inner surface 338 while the second annular channels 320d extend from the inner surface 338 towards the outer surface 334. Thus, the annular channels 320c, 320d are disposed on opposite sides of the thermal choke 369. The first annular channel 320c is disposed in an alternating fashion between adjacent second channels 320d.

In one embodiment, the channels 320a-320d do not span an entire width of a respective thermal chokes 368, 369. That is, the channels 320a-320d define thin bridges between each channel end and the opposing surface. For example, first annular channels 320a have a bridge between the ends thereof and the inner surface 332. In this configuration, the channels 320a-320d greatly increase the surface area for the convection of heat to the external environment around the faceplate 336. Additionally, the cross-section area and/or mass available to conduct heat from the distribution portion 364 towards an outer surface is greatly reduced. Further, here, six channels 320a-320d are shown but any suitable number and configuration thereof to limit heat transfer may be utilized.

It is understood that the size, shape, and number of channels 320a-320d may be selected in relation to a desired rate of heat transfer across the thermal choke 368. Further, the depth, width, and cross section of the channels 320a-320d may be adjusted as desired. Still further, the orientation of the channels may be altered. For example, rather than horizontal channels, the channels may be oriented vertically between and parallel to the outer surfaces 330, 334 and the inner surfaces 332, 338. Any arrangement of channels, gaps, grooves, recesses, or cutouts capable of minimizing heat transfer may be utilized. In one embodiment, the cooling channels 250, 252 of the faceplate 236 are utilized in the faceplate 336.

Seal 370 is disposed within a dovetailed groove in a gasket surface 302a of the thermal choke 368. Seal 356 is similarly disposed within a dovetailed groove in a gasket surface 302b of the thermal choke 369. The seals 370, 356 are disposed outwardly of the channels 320a-320d forming the thermal chokes 368, 369. In this arrangement, thermal heat transfer to the seals 370, 356 from the distribution portion 364 and the heater 374 is reduced or mitigated. Therefore, the heater 374 can heat the faceplate 336, and distribution portion 364 therein, while the seals 370, 356 in the gasket surfaces 302a, 302b are maintained in a temperature range which does not accelerate degradation of the seals 370, 356. In certain embodiments, seals 370, 356 are disposed directly on the surfaces 302a, 302b respectively.

The heater 374 is disposed within the faceplate 336 radially inward from the thermal chokes 368, 369. Here, the heater 374 is a resistive heater. In one embodiment, the heater 374 may be a channel for circulating a heated fluid therein. Any manner of heating the faceplate 336 may be utilized herewith. Additionally, the location of the heater 374 is not limited to that shown in FIG. 3. For example, the heater 374 may be disposed in the flange 380 directly between the thermal chokes 368, 369. In one embodiment, the heater 374 is disposed within the flange 380 radially outward of the thermal chokes 368, 369. Any suitable location of heater 374 and manner of heating may be utilized.

The embodiments described herein advantageously reduce the deposition of contaminant particles on a substrate. The thermal choke as disclosed allows the temperature of the faceplate to be increased to a high temperature, limiting the deposition of contaminant particles, while maintaining the sealing capabilities of the outboard disposed seals.

While the foregoing is directed to embodiments of the present disclosure, other and further embodiments of the disclosure may be devised without departing from the basic scope thereof, and the scope thereof is determined by the claims that follow.

What is claimed is:

1. A faceplate for a processing chamber, comprising:
a body having an upper surface and a lower surface;
a plurality of apertures extending between the upper surface and the lower surface; and
a plurality of thermal chokes disposed on the body surrounding the plurality of apertures, wherein a first thermal choke is disposed on the upper surface of the body and a second thermal choke is disposed on the lower surface of the body.

2. The faceplate of claim 1, wherein the thermal chokes comprise interleaved channels.

3. The faceplate of claim 1, further comprising a heater coupled thereto radially outward of the plurality of thermal chokes.

4. The faceplate of claim 3, further comprising seals, wherein the seals are thermally isolated from the heater by the thermal chokes.

5. The faceplate of claim 4, wherein each seal is disposed in a dovetail groove.

6. The faceplate of claim 1, further comprising a seal disposed at distal ends of each thermal choke of the plurality of thermal chokes.

7. The faceplate of claim 1, further comprising a heater embedded within the body of the faceplate.

8. A faceplate for a processing chamber, comprising:
a body having a plurality of apertures therethrough;
a first thermal choke extending from a first surface of the body; and
a second thermal choke extending from a second surface of the body, wherein the first thermal choke comprises:
a plurality of first channels extending partially through a width of the first thermal choke;
a plurality of second channels extending partially through the width of the first thermal choke, wherein each second channel is disposed between adjacent first channels; and
a cooling channel; and
the second thermal choke comprises:
a plurality of first channels extending partially through a width of the second thermal choke;
a plurality of second channels extending partially through the width of the second thermal choke, wherein each of the plurality of second channels is disposed between adjacent first channels; and
a cooling channel.

9. The faceplate of claim 8, wherein the first thermal choke and the second thermal choke circumscribe the plurality of apertures.

10. The faceplate of claim 8, further comprising a heater.

11. The faceplate of claim 10, further comprising plurality of seals, wherein each of the seals is thermally isolated from the heater by either of the first thermal choke and second thermal choke.

12. The faceplate of claim 8, further comprising a plurality of seals.

13. The faceplate of claim 11, wherein each seal is disposed in a dovetail groove.

14. The faceplate of claim 8, wherein the cooling channel of the first thermal choke and the cooling channel of the second thermal choke are each coupled to a cooling unit.

15. A chamber for processing a substrate, comprising:
a chamber body;
a lid coupled to the chamber body and defining a processing volume; and
a faceplate coupled to the lid, the faceplate comprising:
a body having a first surface and a second surface;
a plurality of apertures disposed through the body;
a first thermal choke extending from the first surface of the body; and
a second thermal choke extending from the second surface of the body, wherein the first thermal choke and the second thermal choke surround the plurality of apertures.

16. The chamber of claim 15, wherein the first thermal choke comprises:
a plurality of first channels extending partially through a width of the first thermal choke;
a plurality of second channels extending partially through the width of the first thermal choke, wherein each second channel is disposed between adjacent first channels; and
the second thermal choke comprises:
a plurality of first channels extending partially through a width of the second thermal choke;
a plurality of second channels extending partially through the width of the second thermal choke, wherein the each second channel is disposed between adjacent first channels.

17. The chamber of claim 16, wherein each of the first thermal choke and the second thermal choke further comprises a cooling channel disposed therein.

18. The chamber of claim 15, further comprising seals, wherein the seals are thermally separated from the body of the faceplate by the first and second thermal chokes.

19. The chamber of claim 15, further comprising a heater embedded in the body of the faceplate.

20. The chamber of claim 15, wherein the faceplate is formed from aluminum, aluminum nitride, aluminum oxide, or a combination thereof.
